(19) United States
(12) Patent Application Publication
(10) Pub. No.: US 2019/0324073 A1
(43) Pub. Date: Oct. 24, 2019

(54) CAPACITIVE SENSOR AND CAPACITIVE SENSOR HEAD

(71) Applicant: SIMPLEX QUANTUM INC., Tokyo (JP)

(72) Inventor: Yoshihiro Mikami, Tokyo (JP)

(21) Appl. No.: 16/011,265

(22) Filed: Jun. 18, 2018

(30) Foreign Application Priority Data
Apr. 19, 2018 (JP) 2018-080531

(51) Int. Cl. G01R 27/26; G01D 5/24

(52) U.S. Cl. CPC G01R 27/2605; G01D 5/24

(57) ABSTRACT

A capacitive sensor includes a sensor head, and a capacitance measurement unit. The sensor head includes a sheet-shaped base material, a measuring electrode on one surface of the base material, and a guard electrode on another surface of the base material. The guard electrode is positioned opposing to the measuring electrode in alignment with the same. The guard electrode has an outer periphery at least partially larger than an outer periphery of a shape formed by the measuring electrode. The capacitance measurement unit supplies an input voltage signal having a predetermined cycle to the measuring electrode, converts an output current signal output therefrom corresponding to the input voltage signal into an output voltage to output the output voltage as an output voltage signal, while supplying a voltage signal having a phase identical to a phase of the input voltage signal.

### CROSS-REFERENCE TO RELATED APPLICATION

This application claims priority pursuant to 35 U.S.C. § 119 from Japanese Patent Application No. 2018-80531, filed on Apr. 19, 2018 of which is incorporated herein by reference.

### BACKGROUND

### Technical Field

The present disclosure relates to a capacitive sensor and a capacitive sensor head.

### Related Art

A capacitive sensor is used for, for example, a touchscreen for inputting information and a sensor for proximity detection of various objects. As is commonly known, by measuring a capacitance between a measuring electrode and a ground or between a pair of measuring electrodes, and detecting a change of the measurement value, the capacitive sensor ensures detecting a contact or an approach of various objects, such as a human body, to the measuring electrode.

For example, Japanese Unexamined Patent Application Publication No. 2017-142270 discloses a capacitance detection device that uses a sensor sheet including a sheet-shaped dielectric layer, and a front side electrode layer and a back side electrode layer formed on a front and a back, respectively, of the dielectric layer.

The capacitance detection device disclosed in Japanese Unexamined Patent Application Publication No. 2017-142270 includes a filter unit for which a predetermined pass frequency band is set in order to remove an external electromagnetic noise superimposed on an output signal from the sensor sheet. However, given that filter units for anti-noise measures as described above must be installed to all the capacitance detection devices when many capacitance detection devices are attempted to be installed for, for example, detecting approach of human body, it is highly possible that it is not permitted for a reason of an installation cost.

The present inventors have considered whether anti-external electromagnetic noise measures can be achieved by a simpler configuration. Then, the inventors have focused on a configuration of a sensor head itself used in the capacitive sensor and succeeded in effectively reducing effects from an external electromagnetic noise and a measurement environment on the measuring electrode by adjusting a configuration of, for example, a shape of the measuring electrode.

### SUMMARY

The present disclosure has been made to solve the above-described and other problems. It is one of the objects to provide the capacitive sensor and the capacitive sensor head that achieve a sufficient resistance against effects of an external electromagnetic noise and a measurement environment by a simple configuration.

A capacitive sensor according to one aspect of the present disclosure for achieving the above-described and other purposes includes a sensor head; and a capacitance measurement unit. The sensor head includes a sheet-shaped base material; a first conducting layer disposed on one surface of the base material; and a second conducting layer disposed on another surface of the base material. The second conducting layer is positioned opposing to the first conducting layer in alignment with the first conducting layer. The second conducting layer has an outer periphery at least partially larger than an outer periphery of a shape formed by the first conducting layer. The capacitance measurement unit supplies an input voltage signal having a predetermined cycle to the first conducting layer, converts an output current signal output from the first conducting layer corresponding to the input voltage signal into an output voltage to output the output voltage as an output voltage signal, and supplies a voltage signal having a phase identical to a phase of the input voltage signal to the second conducting layer.

The base material, the first conducting layer, and the second conducting layer may have a strip shape, and the second conducting layer has both side edges each extending outward with respect to both side edges of the first conducting layer.

The first conducting layer and the second conducting layer may be layers of silver pastes disposed on the surfaces of the base material.

A plurality of the first conducting layers in a strip shape may be disposed to be arranged on the strip-shaped base material in a longitudinal direction of the base material, and the second conducting layers may be disposed on another surface of the base material opposite to the side of the first conducting layer while each of the second conducting layers is in alignment with each of the first conducting layers.

In the above configuration, at least one first connecting layer may be disposed to couple the plurality of first conducting layers mutually and at least one second connecting layer may be disposed to couple the plurality of second conducting layers mutually in width directions of each of the plurality of first conducting layers and the plurality of second conducting layers. In this aspect, the second connecting layer may be disposed opposite to the first connecting layer with respect to the base material, and the second conducting layer may have a width larger than a width of the first conducting layer.

An aspect of the present disclosure includes a capacitive sensor head used in the capacitive sensor.

One aspect of the present disclosure ensures reducing effects of an external electromagnetic noise and a measurement environment during a capacitance measurement with a simple configuration.

### BRIEF DESCRIPTION OF THE DRAWINGS

FIG. 1 is a drawing illustrating an exemplary configuration of a capacitive sensor according to one embodiment of the present disclosure;

FIG. 2 is a schematic diagram illustrating an exemplary configuration of a sensor head and a capacitance measurement unit;

FIG. 3A is a plan view illustrating an exemplary sensor head used in the capacitive sensor in FIG. 1;

FIG. 3B is a bottom view illustrating the exemplary sensor head used in the capacitive sensor in FIG. 1;

FIG. 3C is a cross-sectional view illustrating the exemplary sensor head used in the capacitive sensor in FIG. 1;

FIG. 4A is a plan view illustrating another exemplary sensor head used in the capacitive sensor in FIG. 1;

FIG. 4B is a bottom view illustrating the other exemplary sensor head used in the capacitive sensor in FIG. 1;

FIG. 4C is a cross-sectional view illustrating the other exemplary sensor head used in the capacitive sensor in FIG. 1;

FIG. 5A is a plan view illustrating yet another exemplary sensor head used in the capacitive sensor in FIG. 1;

FIG. 5B is a bottom view illustrating the yet other exemplary sensor head used in the capacitive sensor in FIG. 1; and

FIG. 5C is a cross-sectional view illustrating the yet other exemplary sensor head used in the capacitive sensor in FIG. 1.

### DETAILED DESCRIPTION OF THE EMBODIMENTS

The following describes the present disclosure based on one embodiment with reference to the drawings.

In describing embodiments illustrated in the drawings, specific terminology is employed for the sake of clarity. However, the disclosure of the present specification is not intended to be limited to the specific terminology so selected and it is to be understood that each specific element includes all technical equivalents that have a similar function, operate in a similar manner, and achieve a similar result.

As used herein, the singular forms “a”, “an”, and “the” are intended to include the plural forms as well, unless the context clearly indicates otherwise.

Referring to the drawings, wherein like reference numerals designate identical or corresponding parts throughout the several views, embodiments of the present disclosure are described below.

### Configuration of Capacitive Sensor

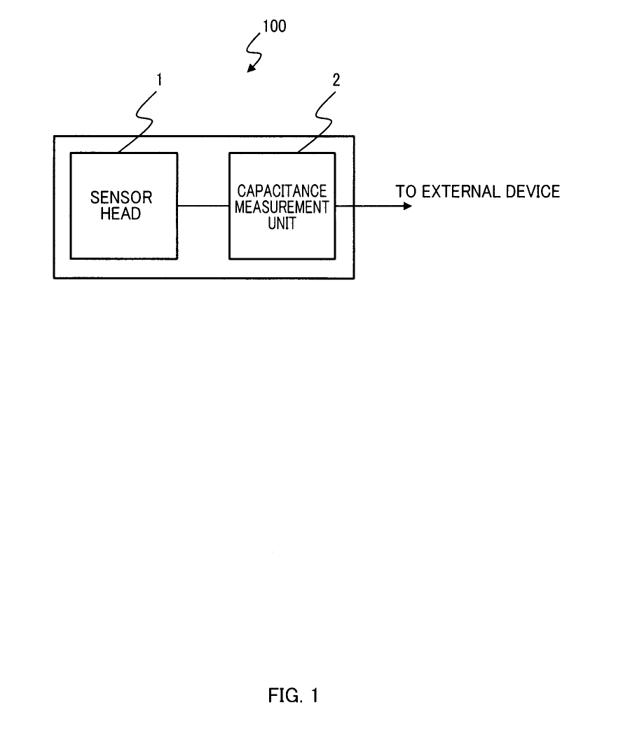

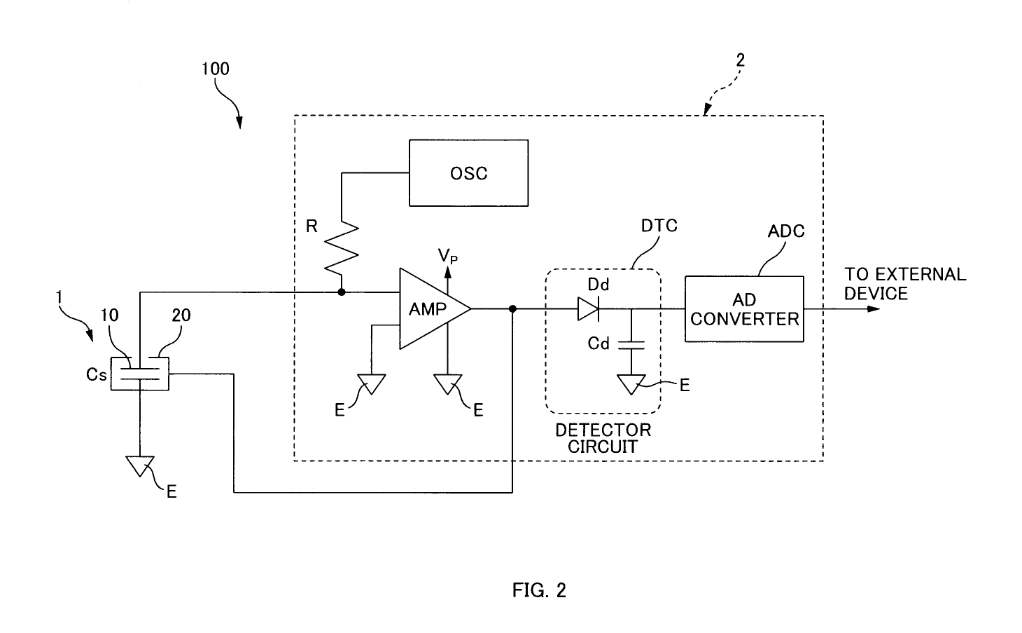

First, an exemplary configuration of a capacitive sensor according to the embodiment will be described. FIG. 1 illustrates the exemplary configuration of the capacitive sensor according to the embodiment. FIG. 2 schematically illustrates an exemplary configuration of a sensor head and a capacitance measurement unit included in the capacitive sensor in FIG. 1.

A capacitive sensor 100 according to the embodiment includes a sensor head 1 and a capacitance measurement unit 2. The sensor head 1 includes a measuring electrode 10, which constitutes a virtual capacitor between a ground and the measuring electrode 10, and a guard electrode 20 disposed in order to reduce effects of an external electromagnetic noise and a measurement environment affecting on an output from the measuring electrode 10. The measuring electrode 10 and the guard electrode 20 are each coupled to the capacitance measurement unit 2. A configuration of the sensor head 1 will be described in details later.

The capacitance measurement unit 2 has a function of supplying a predetermined input voltage signal to the sensor head 1 and converting an output current signal from the measuring electrode 10 into a digital signal indicating a change in a capacitance.

As illustrated in FIG. 2, the sensor head 1 is mainly constituted of the measuring electrode 10 and the guard electrode 20. The measuring electrode 10 constitutes the virtual capacitor between a ground E and the measuring electrode 10. The virtual capacitor has a capacitance Cs. As is already known, a change occurs in the capacitance Cs by an effect of an object with a conductive property, such as a human body, approaching the measuring electrode 10. The capacitance measurement unit 2 measures this change in the capacitance Cs.

The capacitance measurement unit 2 includes oscillator circuit OSC, an amplifier AMP, detection circuit DTC, and an AD converter ADC. The detection circuit DTC has a function of performing an envelope detection on an alternate current output of the amplifier AMP with a diode Dd and a capacitance Cd. The oscillator circuit OSC generates an alternating current signal (input voltage signal) in a predetermined frequency and its output is input to the amplifier AMP via a resistor R. The measuring electrode 10 of the sensor head 1 is coupled between the resistor R and a non-inverted input of the amplifier AMP. In view of this, the resistor R and the capacitance Cs of the virtual capacitor constituted of the measuring electrode 10 divide the alternating current signal from the oscillator circuit OSC, and then the divided alternating current signal is input to the amplifier AMP and the detection circuit DTC. As the capacitance Cs increases, an amplitude of the AC output signal from the amplifier AMP decreases, and accordingly, an output voltage of the detection circuit DTC decreases. In view of this, the output of the detection circuit DTC varies in an analog manner corresponding to the increase of the capacitance Cs regarding the measuring electrode 10. The AD converter ADC generates a digital signal corresponding to an analog value of the capacitance Cs regarding this measuring electrode 10. This digital signal can be transmitted as a value of the capacitance Cs of the measuring electrode 10, in other words, a state quantity indicating whether an object, such as a human body, is positioned close to the measuring electrode 10, to, for example, an external management server computer (external device).

When the variation in the capacitance Cs constituted between the measuring electrode 10 and the ground E is measured as described above, its amount of variation is considerably small. Accordingly, when a conductive body, such as a metallic member, is present near the measuring electrode 10, the measurement circuit becomes equivalent to the circuit that includes another virtual capacitor formed between the measuring electrode 10 and the conductive body coupled in parallel to the virtual capacitor having the capacitance Cs as a detection target. Therefore, there has been an event where measuring a minute amount of variation in the capacitance Cs is almost impossible.

Conventionally in a field of electricity and electronic circuit, an electromagnetic shield is disposed for preventing the effects of the external electromagnetic noise and the above described measurement environment. Specifically, disposing the electromagnetic shield includes employing a shield cable using a method that prevents an electromagnetic induction to a cable core by surrounding a peripheral area of a conductor constituting the cable core of a transmission cable with a meshed shield and coupling the shield to the ground. The inventors have conceived from this shield cable configuration to discover a fact that the effects of the external electromagnetic noise and the measurement environment on the measuring electrode 10 can be effectively cut off. The effects can be effectively cut off by disposing a configuration that corresponds to a shield to be separated from the measuring electrode 10 with an insulating layer interposed, even though the configuration corresponding to the shield is not disposed to surround the measuring electrode 10 as a conductor corresponding to the cable core.

In FIG. 2, the guard electrode 20 corresponds to a shield in the shield cable. While it is illustrated as if the guard electrode 20 surrounds the measuring electrode 10 in FIG. 2 for clarity, the guard electrode 20 is only necessary to be arranged side by side along the measuring electrode 10 with the insulating layer interposed as an embodiment described later indicates.

While an ordinary shield is coupled to the ground, the guard electrode 20 of the embodiment is coupled to the output of the amplifier AMP of the capacitance measurement unit 2. In view of this, an electric potential of the guard electrode 20 changes in a phase identical to that of an electric potential of the measuring electrode 10 coupled to the oscillator circuit OSC. This ensures removing an effect of a stray capacitance between the ground and the measuring electrode 10 to be generated when the guard electrode 20 is coupled to the ground, thereby ensuring more effectively cutting off the effects of, for example, the external electromagnetic noise, to the measuring electrode 10.

### Exemplary Configuration of Sensor Head 1

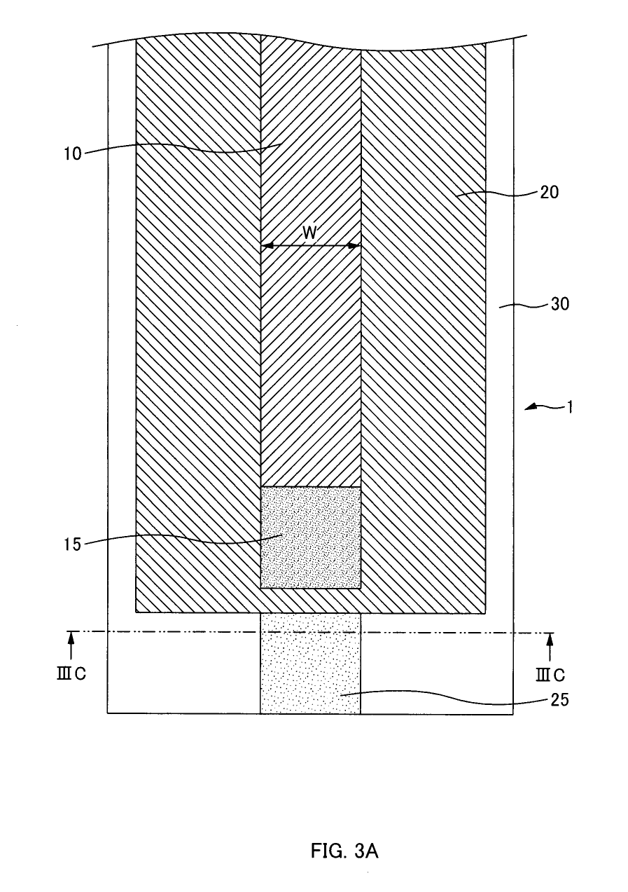

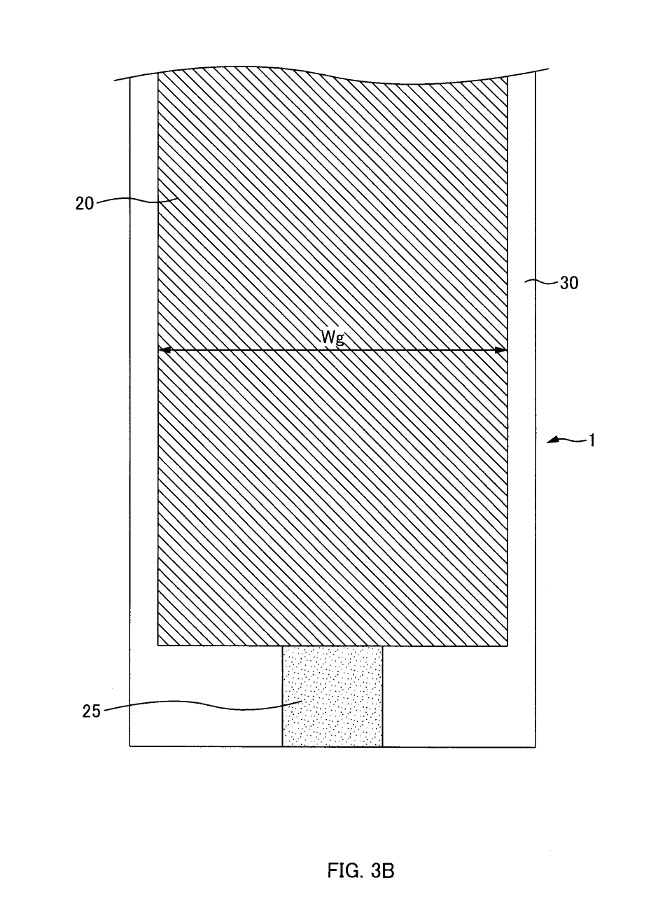

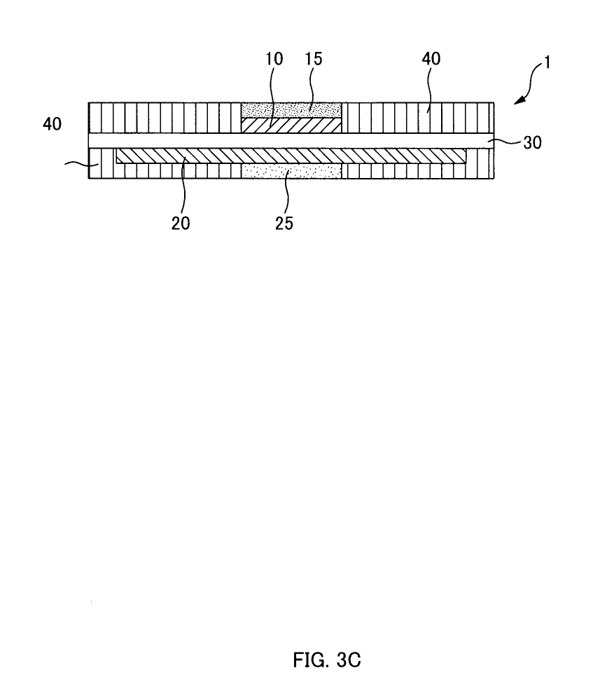

An embodiment of the sensor head 1 used in the capacitive sensor 100 of the embodiment will be described with reference to the drawings. FIG. 3A to FIG. 3C illustrate an exemplary configuration of the sensor head 1 according to one embodiment of the present disclosure. FIG. 3A is a plan view of the sensor head 1, FIG. 3B is a bottom view of the sensor head 1, and FIG. 3C is a cross-sectional view of the sensor head 1. The sensor head 1 is formed into an elongated strip shape. FIG. 3A and FIG. 3B illustrate a state where the sensor head 1 is cut off at a predetermined length from one end portion of the sensor head 1. The sensor head 1 substantially includes the measuring electrode (first conducting layer), the guard electrode 20 (second conducting layer), and a base material 30.

The base material 30 is an elongated strip-shaped member formed of a synthetic resin and constitutes the insulating layer that separates between the measuring electrode 10 and the guard electrode 20. For the synthetic resin as a material, one that has a mechanical durability and a high flexibility is preferably used. However, the material constituting the base material 30 is not specifically limited. A thickness of the base material 30 can be any size as long as it is not extremely large, and can be set, for example, approximately 0.2 to 0.4 mm. A width of the base material 30 can be appropriately determined depending on, for example, a usage.

The base material 30 has one surface on which the measuring electrode 10 is disposed and has the other surface on which the guard electrode 20 is disposed. The measuring electrode 10 and the guard electrode 20 are disposed in a longitudinal direction of the base material 30 with respective predetermined widths. The measuring electrode 10 and the guard electrode 20 are positioned so as to have matched centers in a width direction. The base material 30 of the sensor head 1 is illustrated to be optically transparent in the attached drawings. Therefore, when it is viewed from a side of the measuring electrode 10 as in FIG. 3A, the guard electrode 20 is viewable on both sides of the measuring electrode 10 but when it is viewed from a side of the guard electrode 20 as in FIG. 3B, the measuring electrode 10 is interrupted by the guard electrode 20 and is not viewable.

In this embodiment, the guard electrode 20 has a width Wg set larger than a width W of the measuring electrode 10. As described in relation to FIG. 2, the measuring electrode 10 and the guard electrode 20 are both coupled to the oscillator circuit OSC of the capacitance measurement unit 2. Such a configuration causes the guard electrode 20 to hinder the measuring electrode 10 from constituting the virtual capacitor between another conductive body that is not a ground and the measuring electrode 10, thereby ensuring an accurate measurement of a minute variation in the capacitance Cs between the measuring electrode 10 and the ground. The guard electrode 20 is coupled to a voltage source (output of the amplifier AMP) in a phase identical to that of the measuring electrode 10, and the effect of the stray capacitance between the measuring electrode 10 and the guard electrode 20 are removed; therefore, the measurement accuracy of the capacitance Cs is further improved.

In this embodiment, the measuring electrode 10 and the guard electrode 20 are formed by screen-printing a silver paste on the base material 30. A thickness of the silver paste is only necessary to be set appropriately based on, for example, required specifications on measuring the capacitance Cs and conditions on the manufacturing cost. Note that both the measuring electrode 10 and the guard electrode 20 can be disposed by a method other than screen-printing the silver paste, for example, by a common coating. Alternatively, the measuring electrode 10 and the guard electrode 20 can also be formed by, for example, laminating a conductive material, such as a metal foil with a conductive property, on the base material 30.

The measuring electrode 10 has one end portion that includes a coupling unit 15 and the guard electrode 20 has one end portion that includes a coupling unit 25 for wiring coupling with the capacitance measurement unit 2. Both coupling units 15 and 25 are formed of a conductive material, such as a solder cream, and formed into a rectangular shape in the embodiment. The coupling units 15 and 25 are each coupled to the oscillator circuit OSC of the capacitance measurement unit 2. The surface of the sensor head 1, except for where these coupling units 15 and 25 are, is protected from a mechanical external force by a resist layer 40 formed by the screen-printing. The resist layer 40 may be formed by another method. When, for example, the measuring electrode 10 is formed by laminating the conductive material on the base material 30, protection sheets of an appropriate insulating material may be disposed on the base material 30 so as to cover, for example, the measuring electrode 10. Note that any sides of the surface of the base material 30 can include a layer of an adhesive agent in order to fix the sensor head 1 to the measurement target. In such a case, a release sheet for protecting an adhesive layer is disposed before the use of the sensor head 1.

The sensor head 1 of this embodiment is installed, for example, on a mattress of a bed. In such a case, the sensor head 1 is installed with the measuring electrode 10 in an upper side and the guard electrode 20 in a lower side. For example, when it is assumed that a bed frame is constituted of a metallic material with a conductive property, a virtual capacitor of a large capacity is formed between the measuring electrode 10 and the bed frame without the guard electrode 20. Therefore, accurately measuring a variation of a minute capacitance between the ground and the measuring electrode 10 is impossible or very difficult. In this embodiment, the guard electrode 20, which is provided with an electric potential in a phase identical to that of the measuring electrode 10 and has a width larger than that of the measuring electrode 10, is interposed between the measuring electrode 10 and the bed frame. Therefore, it is possible for the measuring electrode 10 to measure the variation in the capacitance Cs generated depending on whether a human is on the bed or not, in other words, whether an object (human body in this case) is present near the measuring electrode 10 or not without being affected by the presence of the bed frame. A similar effect can be obtained when a capacitance measurement is performed in a room where a floor material with a conductive property is spread all over, such as what is called an access floor or a raised floor. The above performance tremendously reduces a limitation to an environmental condition on the capacitance measurement.

According to the above-described embodiment, the guard electrode 20 cuts off the effects of the external electromagnetic noise and the measurement environment to the measuring electrode 10. Therefore, the variation in the capacitance Cs caused by an approach of an object to the measuring electrode 10 can be taken out as a digital signal via the capacitance measurement unit 2. Then, analyzing a value of the digital signal ensures obtaining whether the object approaches the measuring electrode 10 or not, and in the case where the object approaches the measuring electrode 10, a degree of the approach (distance from the measuring electrode 10).

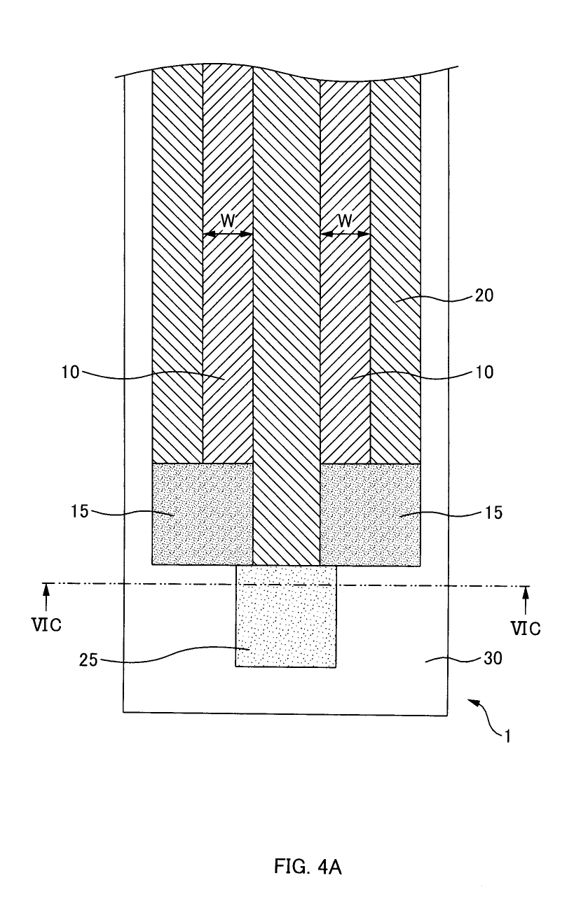

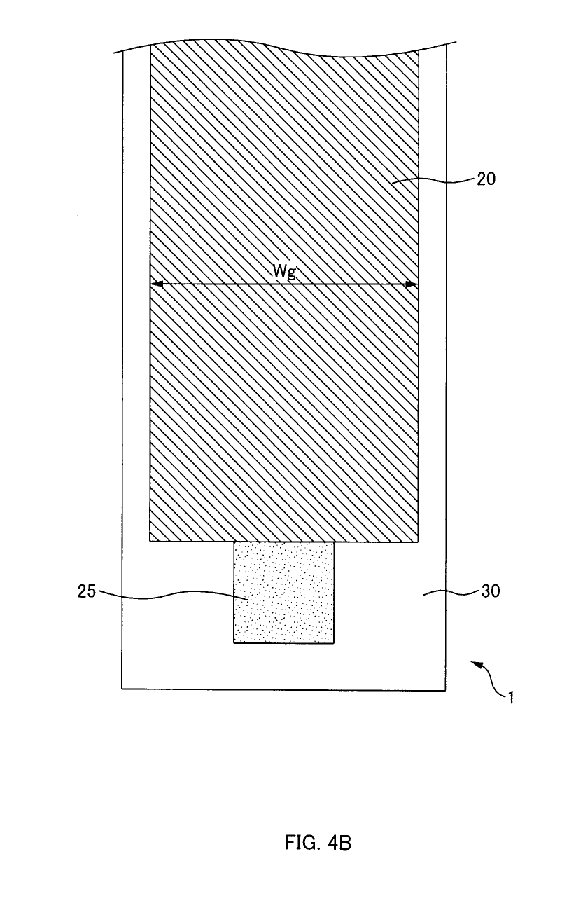

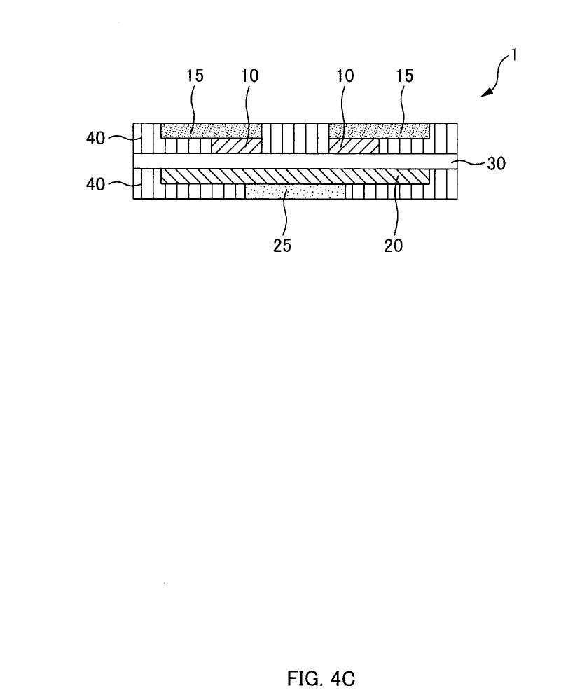

Next, another embodiment of the sensor head 1 used in the capacitive sensor 100 of the embodiment will be described with reference to the drawings. FIG. 4A to FIG. 4C illustrate an exemplary configuration of the sensor head 1 according to a second embodiment of the present disclosure. FIG. 4A is a plan view of the sensor head 1, FIG. 4B is a bottom view of the sensor head 1, and FIG. 4C is a cross-sectional view of the sensor head 1. Note that a component identical or equivalent to that in the prior embodiment has an identical reference numeral attached in the following drawings.

In this embodiment, a configuration including the measuring electrode 10, the guard electrode 20, and the base material 30 is similar to that of a first embodiment described before. However, in this embodiment, while the guard electrode 20 is one, which is identical to the first embodiment, there are disposed two measuring electrodes 10 with a width smaller than that of the first embodiment. The measuring electrodes 10 and the guard electrode 20 include the respective coupling units 15 and 25, similarly to the first embodiment. In this embodiment, the variation in the capacitance Cs generated in the measuring electrode 10 is superimposed and measured, in addition to obtaining an effect similar to that of the first embodiment, thereby ensuring an improved measurement accuracy of the capacitance variation compared with the case of the first embodiment.

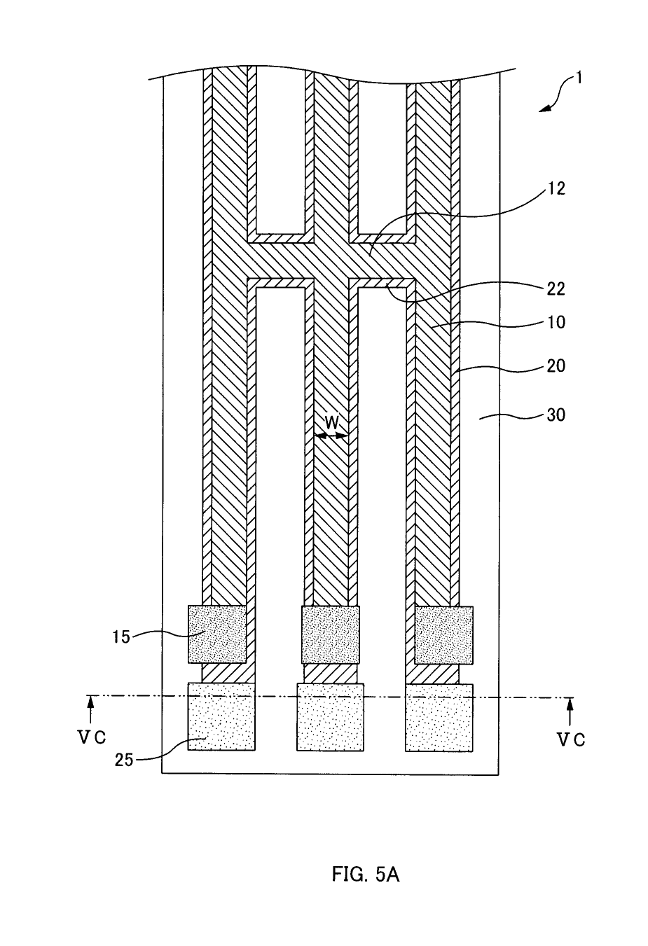

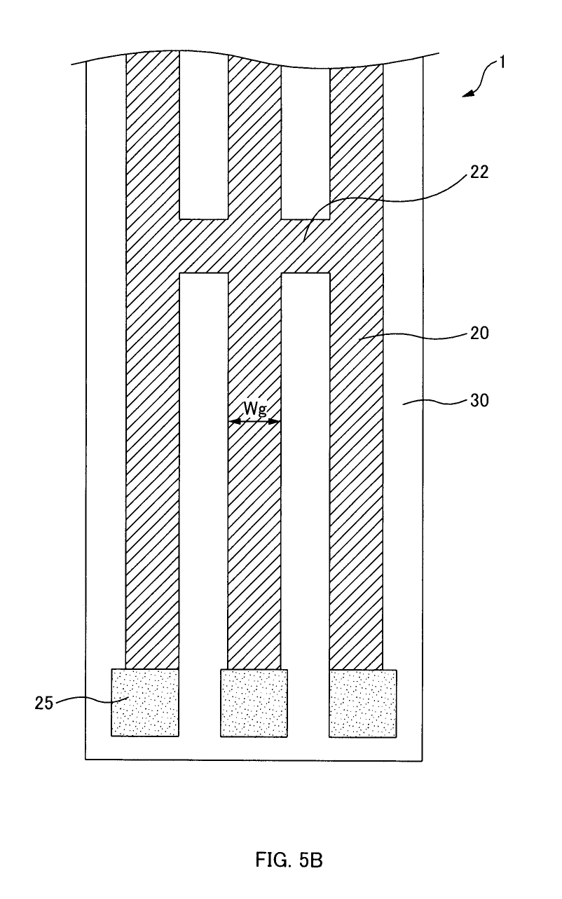

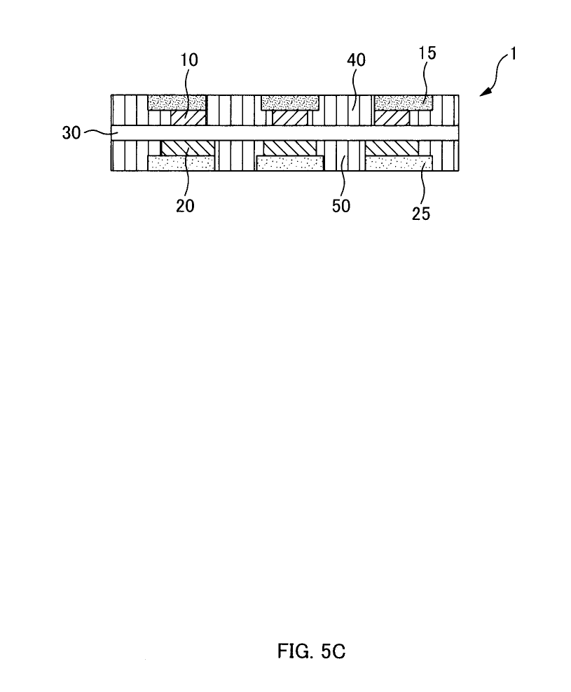

Next, yet another embodiment of the sensor head 1 used in the capacitive sensor 100 of the embodiment will be described with reference to the drawings. FIG. 5A to FIG. 5C illustrate an exemplary configuration of the sensor head 1 according to a third embodiment of the present disclosure. FIG. 5A is a plan view of the sensor head 1, FIG. 5B is a bottom view of the sensor head 1, and FIG. 5C is a cross-sectional view of the sensor head 1.

In this embodiment, a configuration including the measuring electrode 10, the guard electrode 20, and the base material 30 is similar to that of the first embodiment and the second embodiment described before. However, this embodiment is different from the first and second embodiments in that three measuring electrodes 10 and three guard electrodes 20 are disposed. Each of the measuring electrodes 10 and the guard electrodes 20 is disposed on a top surface and a rear surface of the base material 30 such that centers in their width directions are aligned. Between the centers of the respective measuring electrodes 10 and guard electrodes 20 are spaced at an equal distance. The measuring electrodes 10 and the guard electrodes 20 include the respective coupling units 15 and 25, similarly to the first and second embodiments. Note that the guard electrodes 20 in the second embodiment may be separately formed for the respective measuring electrode 10 as in this embodiment.

In this embodiment, as exemplarily illustrated in FIG. 5A and FIG. 5B, bridge patterns (connecting layers) 12 and 22 that electrically and mutually couple the three measuring electrodes 10 and guard electrodes 20 are disposed. Even when any two measuring electrodes 10 and guard electrodes 20 are damaged to be broken, the bridge patterns 12 and 22 maintains a function of the sensor head 1 with the remaining measuring electrode 10 and guard electrode 20. The bridge patterns 12 and 22 can be disposed in a plurality of positions along a longitudinal direction of the sensor head 1. Note that the bridge patterns 12 and 22 are applicable to the measuring electrodes 10 in the second embodiment.

This embodiment ensures reducing a usage of the material, such as the silver paste, used for forming the measuring electrode 10 and the guard electrode 20 more than the case of the embodiments described before, in addition to obtaining an effect similar to those of the first and second embodiments. In view of this, an effect that ensures the reduced manufacturing cost of the sensor head 1 is realized.

### Effect of Sensor Heads According to Embodiments

In order to confirm the effect of the sensor head 1 according to the above-described embodiments of the present disclosure, sensor head samples for confirming effect were made and the capacitance measurement was performed. First, resin sheets having a length of 970 mm, a width of 260 mm, and a thickness of 0.4 mm were prepared as the base material 30 for the sensor head samples.

Three kinds of sensor head samples were prepared by screen-printing the silver pastes on the resin sheets.

Sample 1 The silver paste was formed to have a width of 30 mm to be the measuring electrode 10 and no guard electrode 20 was disposed.

Sample 2 Three measuring electrodes 10 formed of the silver pastes having 1 mm widths were disposed at a pitch of 10 mm and no guard electrode 20 was disposed.

Sample 3 In Sample 2, the guard electrode 20 having a 2 mm width was disposed for providing a shield of in-phase signal.

Each of the measuring electrodes 10 and the guard electrodes 20 included the coupling units 15 and 25 of carbon layers at respective one end portions.

Each of the measuring electrodes 10 was coupled to a non-inverting input terminal of an operational amplifier that operates at 5 V of power supply voltage, and the output voltages were measured with a circuit tester. The guard electrode 20 was coupled to an output of the operational amplifier, and supplied with a voltage signal having a phase identical to that of the measuring electrode 10. The output of the operational amplifier was digitized by an AD converter having a 10 bit of resolution and a 1.1 V of internal reference voltage. It was calculated from the specification of the used operational amplifier that at least a change of 0.002 V was necessary in order to detect an input voltage change with the AD converter. In addition to this, a measurement error of the used circuit tester was considered, and then it was estimated that an approach of an object to the measuring electrode 10 was detectable when a change of 0.007 V or more was generated in the output voltage. Note that the object in this measurement was a human body. The analysis was made by measuring the output voltages when a hand approaches the samples from a distant place, which is equivalent to a “state human body is not detected”, at pitches of each 50 mm from 250 mm to 0 mm for distances from the measuring electrode 10. The samples were installed in a space or on a floor.

Table 1 indicates results of measuring the output voltages for the sensor head samples 1 to 3. The measurement environment was a room interior where the floor material with the conductive property was spread all over. The measurement type indicates how each of the samples was disposed in this room interior. “IN SPACE” indicates a state where the sample was supported perpendicular to a floor surface by a supporter with an insulating property such that a lower end of the sample was positioned at 600 mm above from the floor of the room interior. “ON FLOOR” indicates a state where the sample was placed on the floor surface of the room interior. The human body detection distance indicates a distance between the human body and the measuring electrode 10 when a change value of the output voltage becomes 0.007 V or more for the first time in the output voltage measurement.

TABLE 1

| | MEASURE- | HUMAN BODY |
|---|---|---|
| | MENT | DETECTION |
| MEASUREMENT SAMPLE | TYPE | DISTANCE |
| MEASURING ELECTRODE | IN SPACE | 250 mm |
| WIDTH 30 mm | ON FLOOR | 50 mm |
| NO GUARD ELECTRODE | | |
| MEASURING ELECTRODE | IN SPACE | 250 mm |
| WIDTH 1 mm × 3 | ON FLOOR | 0 mm |
| NO GUARD ELECTRODE | | |
| MEASURING ELECTRODE | IN SPACE | 150 mm |
| WIDTH 1 mm × 3 | ON FLOOR | 100 mm |
| WITH GUARD ELECTRODE | | |

As illustrated in Table 1, all the samples could detect an approach or a contact of human body in each of the measurement types. Meanwhile, all of each sample had a human body detection distance small when the measurement state was on floor, compared with that in space. The reason of this results is thought to be an effect of the conductive body disposed on the floor surface has caused a degradation of a measurement sensitivity of the sensor head. Among those, Sample 3 including the guard electrode 20 has a decreased difference of the human body detection distance between in space and on floor compared with the other samples. This was assumed that the disposition of the guard electrode 20 has provided an effect to suppress the effect by the conductive body on the floor surface from affecting on the capacitance measurement. Thus, the effect of the present disclosure could be confirmed through the measurement test for the sensor head samples. Note that when a plurality of the measuring electrodes 10 having considerably small widths as in Samples 2 and 3 of the embodiments, disposing the bridge patterns 12 and 22 as in the third embodiment is preferable since a redundant system can be constituted for a case where any of the measuring electrode 10 is cut due to, for example, a deformation of the base material 30.

As described above, the embodiment of the present disclosure ensures providing a capacitive sensor and a capacitive sensor head that achieve a sufficient resistance against the effects of the external electromagnetic noise and the measurement environment with a simple configuration.

Although the present disclosure has been described with reference to example embodiments, those skilled in the art will recognize that various changes and modifications may be made in form and detail without departing from the spirit and scope of the claimed subject matter.

What is claimed is:

1. A capacitive sensor comprising:
a sensor head; and
a capacitance measurement unit, wherein
the sensor head includes:
a sheet-shaped base material;
a first conducting layer disposed on one surface of the base material; and
a second conducting layer disposed on another surface of the base material, the second conducting layer positioned opposing to the first conducting layer in alignment with the first conducting layer, the second conducting layer having an outer periphery at least partially larger than an outer periphery of a shape formed by the first conducting layer,
the capacitance measurement unit supplies an input voltage signal having a predetermined cycle to the first conducting layer, converts an output current signal output from the first conducting layer corresponding to the input voltage signal into an output voltage to output the output voltage as an output voltage signal, and
the capacitance measurement unit supplies a voltage signal having a phase identical to a phase of the input voltage signal to the second conducting layer.

2. The capacitive sensor according to claim 1, wherein
the base material, the first conducting layer, and the second conducting layer have a strip shape, and the second conducting layer has both side edges each extending outward with respect to both side edges of the first conducting layer.

3. The capacitive sensor according to claim 1, wherein
the first conducting layer and the second conducting layer are layers of silver pastes disposed on the surfaces of the base material.

4. The capacitive sensor according to claim 1, wherein
a plurality of the first conducting layers in a strip shape are disposed to be arranged on the strip-shaped base material in a longitudinal direction of the base material, and the second conducting layers are disposed on another surface of the base material opposite to the side of the first conducting layer, each of the second conducting layers in alignment with each of the first conducting layers.

5. The capacitive sensor according to claim 4, further comprising:
at least one first connecting layer coupling the plurality of first conducting layers mutually and at least one second connecting layer coupling the plurality of second conducting layers mutually in width directions of each of the plurality of first conducting layers and the plurality of second conducting layers, wherein
the second connecting layer is disposed opposite to the first connecting layer with respect to the base material, and
the second conducting layer has a width larger than a width of the first conducting layer.

6. A capacitive sensor head used in the capacitive sensor according to claim 1.
